(19) United States
(12) Patent Application Publication
(10) Pub. No.: US 2008/0072956 A1
(43) Pub. Date: Mar. 27, 2008

(54) Solar cell with antireflective coating comprising metal fluoride and/or silica and method of making same

(75) Inventors: Pramod K. Sharma, Ann Arbor, MI (US); Nathan P. Mellott, Northville, MI (US); Thomas J. Taylor, Northville, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/516,671

(22) Filed: Sep. 7, 2006

(51) Int. Cl. H01L 31/00

(52) U.S. Cl. 136/256

(57) ABSTRACT

There is provided a coated article (e.g., solar cell) that includes an improved anti-reflection (AR) coating. This AR coating functions to reduce reflection of light from the light incident glass substrate, thereby allowing more light within the solar spectrum to pass through the incident glass substrate and reach the photovoltaic semiconductor so that the solar cell can be more efficient. In certain example embodiments of this invention, the AR coating may be of or include a composite of a metal fluoride(s) and silica (SiO₂). The metal may be Mg, Ca, or the like, in certain example embodiments of this invention. Thus, in certain example embodiments of this invention, the AR coating may be of or include a composite of (a) MgF₂ and/or CaF₂, and (b) silica.

This invention relates to a coated article that includes an antireflective (AR) coating supported by a glass substrate or other type of substrate. In certain example embodiments of this invention, the AR coating may be of or include a composite of a metal fluoride(s) and silica (SiO₂). The metal may be Mg, Ca, or the like in certain example embodiments of this invention. Thus, in certain example embodiments of this invention, the AR coating may be of or include a composite of (a) MgF₂ and/or CaF₂, and (b) silica. In certain example embodiments, the coated article may be used in connection with a solar cell, but this invention is applicable to other types of coated articles as well.

### BACKGROUND OF THE INVENTION

Glass is desirable for numerous properties and applications, including optical clarity and overall visual appearance. For some example applications certain optical properties (e.g., light transmission, reflection and/or absorption) are desired to be optimized. For example, in certain example instances, reduction of light reflection from the surface of a glass substrate (e.g., superstrate or any other type of glass substrate) is desirable for storefront windows, display cases, solar cells, picture frames, other types of windows, and so forth.

Solar cells/modules are known in the art. Glass is an integral part of most common commercial photovoltaic modules (e.g., solar cells), including both crystalline and other thin film types. A solar cell/module may include, for example, a photoelectric transfer film made up of one or more layers located between a pair of substrates. One or more of the substrates may be of glass. The glass may form a substrate, protecting underlying device(s) and/or layer(s) for converting solar energy to electricity. Example solar cells are disclosed in U.S. Pat. Nos. 4,510,344, 4,806,436, 6,506,622, and 5,977,477, the disclosures of which are hereby incorporated herein by reference.

Substrate(s) in a solar cell/module are sometimes made of glass. Incoming radiation passes through the incident glass substrate of the solar cell before reaching the active/absorbing layer(s) (e.g., photoelectric transfer film such as a semiconductor) of the solar cell. Radiation that is reflected by the incident glass substrate does not make its way into the active layer(s) of the solar cell thereby resulting in a less efficient solar cell. In other words, it would be desirable to decrease the amount of radiation that is reflected by the incident substrate, thereby increasing the amount of radiation that makes its way to the active layer(s) of the solar cell. In particular, the power output of a solar cell or photovoltaic module is dependent upon the amount of light, or number of photons, within a specific range of the solar spectrum that pass through the incident glass substrate and reach the photovoltaic semiconductor.

Thus, it will be appreciated that there exists a need for an improved antireflective (AR) coating, for solar cells or other applications, to reduce reflection off of a light incident glass substrate.

### BRIEF SUMMARY OF EXAMPLE EMBODIMENTS OF THE INVENTION

In certain example embodiments of this invention, an improved anti-reflection (AR) coating is provided on an incident glass substrate of a solar cell or the like. This AR coating functions to reduce reflection of light from the glass substrate, thereby allowing more light within the solar spectrum to pass through the incident glass substrate and reach the photovoltaic semiconductor so that the solar cell can be more efficient. In other example embodiments of this invention, such an AR coating may be used in applications other than solar cells, such as in storefront windows, display cases, picture frames, other types of windows, and the like.

In certain example embodiments of this invention, the AR coating may be of or include a composite of a metal fluoride(s) and silica (SiO₂). The metal may be Mg, Ca, and/or the like in certain example embodiments of this invention. Thus, in certain example embodiments of this invention, the AR coating may be of or include a composite of (a) MgF₂ and/or CaF₂, and (b) silica. Such AR coatings for a solar cell are advantageous in that they may permit a solar cell or the like to be provided with an easy to fabricate, inexpensive and/or efficient AR coating on a large area basis. Moreover, such AR coatings are advantageous with respect to mechanical durability, are able to be heat treated (e.g., thermally tempered) along with the underlying glass, and/or are excellent AR coatings thereby permitting more solar radiation to reach the active layer(s) so as to increase power of the solar cell.

Optionally, the AR coating may be used in connection and be supported by a light incident glass substrate made of low-iron type soda-lime-silica glass in certain example embodiments of this invention. The low-iron nature of the glass may permit it to be a high-transmission type glass in certain instances, which can increase the amount of light that can pass through the glass and reach the semiconductor of the photovoltaic device in certain example embodiments of this invention.

The glass substrate, with the AR coating thereon, may or may not be heat treated (e.g., thermally tempered) in certain example embodiments of this invention. Thermal tempering involves heating the glass with the coating thereon using temperature(s) of from about 580-850 degrees C.

In certain example embodiments of this invention, there is provided a photovoltaic device comprising: a photovoltaic layer and at least a glass substrate on a light incident side of the photovoltaic layer; an anti-reflection coating provided on the glass substrate, the anti-reflection coating being located on a light-incident side of the glass substrate; and wherein the anti-reflection coating comprises a layer comprising (a) magnesium fluoride and/or calcium fluoride, and (b) silica.

In certain example embodiments of this invention, there is provided a photovoltaic device comprising a photovoltaic layer and at least a glass substrate on a light incident side of the photovoltaic layer; an anti-reflection coating provided on the glass substrate, the anti-reflection coating being located on a light-incident side of the glass substrate; and wherein the anti-reflection coating comprises a layer comprising at least one metal fluoride and silica.

In still further example embodiments of this invention, there is provided a method of making a photovoltaic device, the method comprising providing a glass substrate; mixing a metal fluoride inclusive sol and a silica inclusive sol to form a mixture solution; depositing the mixture solution including the metal fluoride inclusive sol and the silica inclusive sol onto the glass substrate; heating the glass substrate with the mixture solution thereon, thereby forming a coated article including an anti-reflective coating on the glass substrate; and coupling the coated article including the anti-reflective coating and glass substrate to at least a photovoltaic layer in making the photovoltaic device.

### BRIEF DESCRIPTION OF THE DRAWINGS

FIG. 1 is a cross sectional view of a coated article including an antireflective (AR) coating according to an example embodiment of this invention.

FIG. 2 is a cross sectional view of a solar cell that may use the AR coating of FIG. 1 according to an example embodiment of this invention.

FIG. 3 is a percent transmission vs. wavelength graph illustrating characteristics of coated articles of Examples 1 and 2.

FIG. 4 is a percent transmission vs. wavelength graph illustrating characteristics of coated articles of Examples 3-7.

FIG. 5 is a percent transmission vs. wavelength graph illustrating characteristics of a coated article of Example 8.

### DETAILED DESCRIPTION OF EXAMPLE EMBODIMENTS OF THE INVENTION

Referring now more particularly to the accompanying drawings in which like reference numerals indicate like parts throughout the several views.

Photovoltaic devices such as solar cells convert solar radiation and other light into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device. In certain example embodiments, single junction amorphous silicon (a-Si) photovoltaic devices include at least three semiconductor layers making up an absorbing semiconductor film. In particular, a p-layer, an n-layer and an i-layer which is intrinsic can make up the absorbing semiconductor film in certain example instances. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components.

It is noted that while certain example embodiments of this invention are directed toward amorphous-silicon based photovoltaic devices, this invention is not so limited and may be used in conjunction with other types of photovoltaic devices in certain instances including but not limited to devices including other types of semiconductor material, tandem thin-film solar cells, CdS/CdTe based solar cells, crystalline solar cells, and the like.

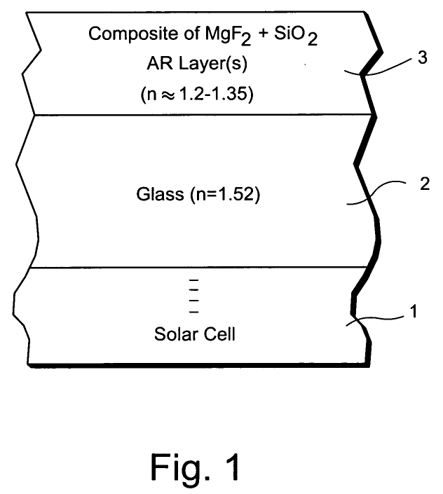

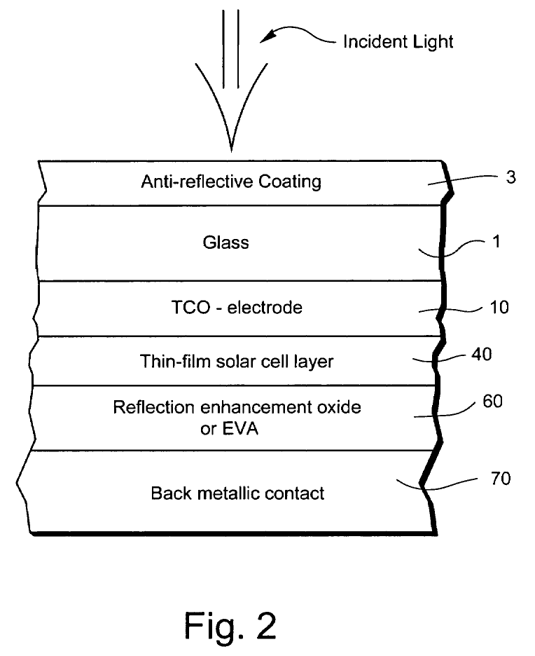

FIG. 1 is a cross sectional view of a coated article according to an example embodiment of this invention, and FIG. 2 is a cross sectional view of the coated article of FIG. 1 as used in connection with an example photovoltaic device in an example embodiment of this invention. The photovoltaic device includes transparent front or light incident glass substrate 1 with an AR coating 3 thereon, front electrode or contact 10 which is of or includes a transparent conductive oxide (TCO) layer such as tin oxide, fluorine-doped tin oxide, zinc oxide, aluminum-doped zinc oxide, indium tin oxide, indium zinc oxide, or the like, active or absorbing semiconductor film 50 of one or more semiconductor layer(s) (e.g., including at least three layers of p, i, and n types in certain example instances), optional reflection enhancement oxide or EVA 60, and optional back electrode or contact 70 which may be of a TCO or a metal. Furthermore, optionally, an optional encapsulant or adhesive (not shown) of a material such as ethyl vinyl acetate (EVA) or the like, and an optional superstrate (not shown) of a material such as glass may be provided below the back contact 70 in this order. Of course, other layer(s) which are not shown may also be provided in the device.

Front glass substrate 1 and/or rear superstrate (not shown) may be made of soda-lime-silica based glass in certain example embodiments of this invention. While these substrates may be of glass in certain example embodiments of this invention, other materials such as quartz or the like may instead be used. Moreover, the superstrate (not shown) at the rear of the photovoltaic device is optional in certain instances. Glass of substrate 1 and/or of the superstrate may or may not be thermally tempered and/or patterned in certain example embodiments of this invention. Additionally, it will be appreciated that the word “on” as used herein covers both a layer/film being directly on and indirectly on something, with other layers possibly being located therebetween.

While the AR coating is provided on a light incident glass substrate of a photovoltaic device in FIGS. 1-2, this invention is not so limited. Alternatively, the antireflective (AR) coating 3 may be provided for coated articles such as storefront windows, display cases, picture frames, other types of windows, and the like; and/or may be provided on the rear glass superstrate of a photovoltaic device.

Referring to FIGS. 1-2, in certain example embodiments of this invention, improved anti-reflection (AR) coating 3 is provided on the light incident side of light incident glass substrate 1 of the photovoltaic device. This AR coating 3 functions to reduce reflection of light from the glass substrate 1, thereby allowing more light within the solar spectrum to pass through the incident glass substrate 1 and reach the photovoltaic semiconductor 50 so that the solar cell can be more efficient and have increased power. The AR coating 3 may be of or include a composite of a metal fluoride(s) and porous silica (SiO₂). The metal may be Mg, Ca, and/or the like in certain example embodiments of this invention. Thus, in certain example embodiments of this invention, the AR coating 3 may be of or include a composite of (a) magnesium fluoride such as MgF₂ and/or calcium fluoride such as CaF₂, and (b) silica. Such AR coatings 3 for a photovoltaic device such as a solar cell are advantageous in that they may permit a solar cell or the like to be provided with an easy to fabricate, inexpensive and/or efficient AR coating on a large area basis. Moreover, such AR coatings are advantageous with respect to mechanical durability, are able to be heat treated (e.g., thermally tempered) along with the underlying glass, and/or are excellent AR coatings thereby permitting more solar radiation to reach the active layer(s) so as to increase power of the solar cell.

The metal fluoride portion of the composite low-index AR coating 3 is advantageous in that it permits the AR coating to realize a low refractive index (n). In certain example embodiments of this invention, the glass substrate 1 may have a refractive index (n) of from about 1.48 to 1.60 (e.g., about 1.52), whereas the AR coating 3 (which may be of a single layer in certain example embodiments) may have a refractive index (n) of from about 1.20 to 1.45, more preferably from about 1.23 to 1.40, and most preferably from about 1.25 to 1.35 (at 450 nm).

The low refractive index (n) of AR coating 3 is advantageous in that it allows less reflection so that more light can pass through the glass substrate 1 and reach the active semiconductor layer(s) of the photovoltaic device. Meanwhile, the silica portion of the AR coating 3 is advantageous in that it increases the solar transmission of the coating 3 so that less light is absorbed by the coating; again, this increases the amount of light which can pass through the glass substrate 1 and reach the active semiconductor layer(s) of the photovoltaic device whereby power of the device can be increased. Moreover, the silica portion of the AR coating 3 is also advantageous in that it increases the mechanical durability of the coating 3, and permits it to be used in many different environments with less risk of damage.

In certain example embodiments of this invention, the metal fluoride (e.g., MgF₂ and/or CaF₂) portion of the AR coating 3 may make up from about 0.5 to 50% of the coating (weight percentage), more preferably from about 1-45%, even more preferably from about 1-25%, and most preferably from about 1-15% of the coating 3; the remainder of the coating may be made up of silica and/or other element(s). In certain example embodiments of this invention, the AR coating 3 includes at least about 50% silica, more preferably at least about 60% silica, even more preferably at least about 70% silica, and possibly at least about 85% silica (weight percentage).

Yet another example advantage of coating 3 is that it may consist of only a single layer in certain example embodiments of this invention, thereby reducing the number of steps needed to form the AR coating. While the AR coating 3 may be of only a single layer in certain example embodiments, it is possible that a multi-layer coating may be used for coating 3 in other example embodiments of this invention.

AR coating 3 may be deposited on the glass substrate 1 in any suitable manner, including but not limited to using spin coating, dip coating, or flow coating techniques. The AR coating 3 may be formed as follows in certain example instances. A Mg inclusive salt such as magnesium acetate, or Mg inclusive carboxylate salt, or any other Mg inclusive salt, may be dissolved in a solvent such as alcohol, propanol, ethylene glycol, other glycol, or the like so as to be in liquid form and form a solution. As another example, the solution may be formed by causing magnesium ethoxide or the like to be dissolved in a solvent such as propanol (e.g., propanol-2). The solution may then be mixed with an acid or the like including F. Then, the resulting sol or the like may be mixed with a silica inclusive sol and then applied via spin coating onto, directly or indirectly, a glass substrate 1. Then, the coated substrate may be heat treated for thermal tempering, curing, and/or the like (e.g., for from about 1-15 minutes, more preferably from about 2-10 minutes). The heat treated coated article, including the tempered glass substrate 1 with AR coating 3 thereon, may then be used in making a photovoltaic device as the light incident substrate of such a device.

For purposes of example and without limitation, coating 3 may be from about 0.5 to 15 μm thick in certain example embodiments of this invention, more preferably from about 1-10 μm thick.

In certain example embodiments of this invention, high transmission low-iron glass may be used for glass substrate 1 in order to further increase the transmission of radiation (e.g., photons) to the active layer(s) 50 of the solar cell or the like. For example and without limitation, the glass substrate 1 may be of any of the glasses described in any of U.S. patent application Ser. Nos. 11/049,292 and/or 11/122,218, the disclosures of which are hereby incorporated herein by reference.

Certain glasses for glass substrate 1 (which or may not be patterned in different instances) according to example embodiments of this invention utilize soda-lime-silica flat glass as their base composition/glass. In addition to base composition/glass, a colorant portion may be provided in order to achieve a glass that is fairly clear in color and/or has a high visible transmission. An exemplary soda-lime-silica base glass according to certain embodiments of this invention, on a weight percentage basis, includes the following basic ingredients:

### Example Base Glass

| Ingredient | Wt. % |
|---|---|
| SiO₂ | 67–75% |
| Na₂O | 10–20% |
| CaO | 5–15% |
| MgO | 0–7% |
| Al₂O₃ | 0–5% |
| K₂O | 0–5% |
| Li₂O | 0–1.5% |
| BaO | 0–1% |

Other minor ingredients, including various conventional refining aids, such as SO₃, carbon, and the like may also be included in the base glass. In certain embodiments, for example, glass herein may be made from batch raw materials silica sand, soda ash, dolomite, limestone, with the use of sulfate salts such as salt cake (Na₂SO₄) and/or Epsom salt (MgSO₄×7H₂O) and/or gypsum (e.g., about a 1:1 combination of any) as refining agents. In certain example embodiments, soda-lime-silica based glasses herein include by weight from about 10-15% Na₂O and from about 6-12% CaO.

In addition to the base glass above, in making glass according to certain example embodiments of the instant invention the glass batch includes materials (including colorants and/or oxidizers) which cause the resulting glass to be fairly neutral in color (slightly yellow in certain example embodiments, indicated by a positive b* value) and/or have a high visible light transmission. These materials may either be present in the raw materials (e.g., small amounts of iron), or may be added to the base glass materials in the batch (e.g., cerium, erbium and/or the like). In certain example embodiments of this invention, the resulting glass has visible transmission of at least 75%, more preferably at least 80%, even more preferably of at least 85%, and most preferably of at least about 90% (sometimes at least 91%) (Lt D65). In certain example non-limiting instances, such high transmissions may be achieved at a reference glass thickness of about 3 to 4 mm. In certain embodiments of this invention, in addition to the base glass, the glass and/or glass batch comprises or consists essentially of materials as set forth in Table 2 below (in terms of weight percentage of the total glass composition):

### Example Additional Materials in Glass

| | | | Most |
|---|---|---|---|
| Ingredient | General (Wt. %) | More Preferred | Preferred |
| total iron | 0.001–0.06% | 0.005–0.04% | 0.01–0.03% |
| (expressed as Fe₂O₃): | | | |
| cerium oxide: | 0–0.30% | 0.01–0.12% | 0.01–0.07% |
| TiO₂ | 0–1.0% | 0.005–0.1% | 0.01–0.04% |
| erbium oxide: | 0.05 to 0.5% | 0.1 to 0.5% | 0.1 to 0.35% |

In certain example embodiments, the total iron content of the glass is more preferably from 0.01 to 0.06%, more preferably from 0.01 to 0.04%, and most preferably from 0.01 to 0.03%. In certain example embodiments of this invention, the colorant portion is substantially free of other colorants (other than potentially trace amounts). However, it should be appreciated that amounts of other materials (e.g., refining aids, melting aids, colorants and/or impurities) may be present in the glass in certain other embodiments of this invention without taking away from the purpose(s) and/or goal(s) of the instant invention. For instance, in certain example embodiments of this invention, the glass composition is substantially free of, or free of, one, two, three, four or all of: erbium oxide, nickel oxide, cobalt oxide, neodymium oxide, chromium oxide, and selenium. The phrase “substantially free” means no more than 2 ppm and possibly as low as 0 ppm of the element or material. It is noted that while the presence of cerium oxide is preferred in many embodiments of this invention, it is not required in all embodiments and indeed is intentionally omitted in many instances. However, in certain example embodiments of this invention, small amounts of erbium oxide may be added to the glass in the colorant portion (e.g., from about 0.1 to 0.5% erbium oxide).

The total amount of iron present in the glass batch and in the resulting glass, i.e., in the colorant portion thereof, is expressed herein in terms of Fe₂O₃ in accordance with standard practice. This, however, does not imply that all iron is actually in the form of Fe₂O₃ (see discussion above in this regard). Likewise, the amount of iron in the ferrous state (Fe⁺²) is reported herein as FeO, even though all ferrous state iron in the glass batch or glass may not be in the form of FeO. As mentioned above, iron in the ferrous state (Fe²⁺; FeO) is a blue-green colorant, while iron in the ferric state (Fe³⁺) is a yellow-green colorant; and the blue-green colorant of ferrous iron is of particular concern, since as a strong colorant it introduces significant color into the glass which can sometimes be undesirable when seeking to achieve a neutral or clear color. It is noted that the light-incident surface of the glass substrate 1 may be flat or patterned in different example embodiments of this invention. Moreover, it is noted that other types of glass, other than that discussed above, may be used for substrate 1 in certain other embodiments of this invention.

The following examples are provided for purposes of example only. The following examples are examples of different example embodiments of this invention.

### EXAMPLE 1

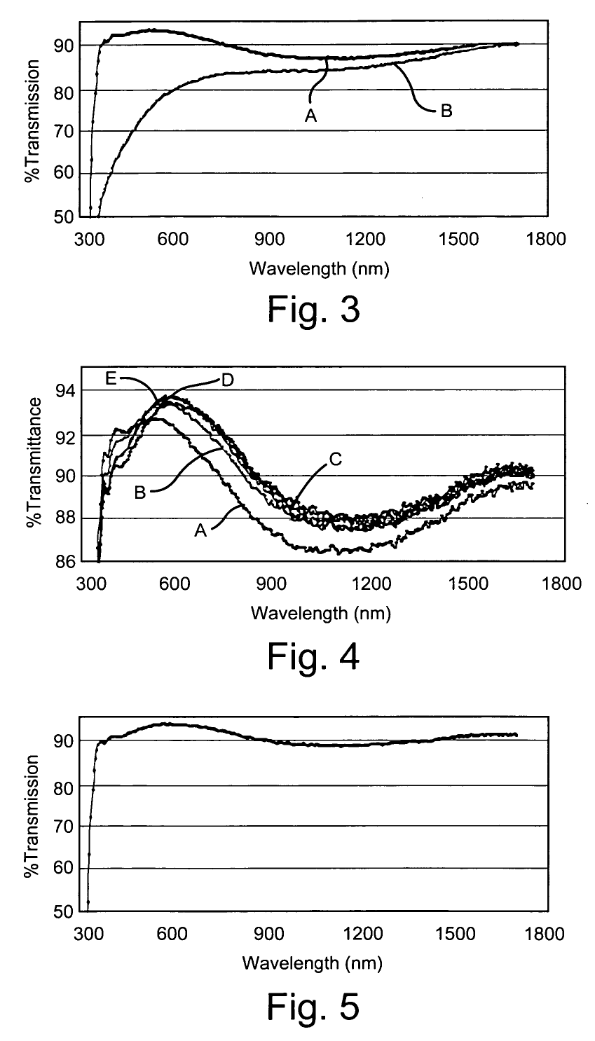

In Example 1, 2.14 grams of magnesium acetate (Mg(CH₃COO)₂), an example Mg inclusive salt, was dissolved in 15 ml of propanol-2. Then 4 ml of trifluoro acid (TFA) and 4 ml of deionized water were added. The solution was stirred for 2 hrs. The experiment was done with ExtraClear low iron glass available from Guardian Industries Corp. The MgF₂ film was fabricated by spin coating this solution onto the ExtraClear glass substrate 1 using an example spin coating technique of 2650 rpm for 30 seconds. Curing is optional. This resulted in a glass substrate 1 with an AR coating 3 thereon, the AR coating 3 being made of purely MgF₂. The glass substrate 1 with the resulting AR coating 3 thereon was then heat treated in furnace at 625° C. for 3 and a half minutes for thermal tempering. The optical spectra of this coating 3 on glass substrate 1 is shown as line A in FIG. 3. Moreover, this MgF₂ AR coating 3 was measured to increase the light transmission through the glass substrate 1 by 1.5%, thereby increasing the power (theoretical energy output) of the photovoltaic device by 1.9% (W/m²), when used in a solar cell as shown in FIG. 2. Note that in all Examples herein, the power increases for photovoltaic devices assumed a crystalline silicon based photovoltaic solar cell for purposes of reference. While the AR coating of this Example was excellent optically, it was not very durable from a mechanical perspective.

### EXAMPLE 2

In Example 2, 3.16 grams of calcium acetate was dissolved in 15 ml of propanol-2. Then, 4 ml of trifluoro acid (TFA) and 4 ml of deionized water were added. The solution was stirred for 2 hrs. The experiment was done with ExtraClear low iron glass available from Guardian Industries Corp., as was the case with all other Examples herein. The CaF₂ film was fabricated by spin coating this solution onto the ExtraClear glass substrate 1 using an example spin coating technique of 2650 rpm for 30 seconds. This resulted in a glass substrate 1 with coating 3 thereon, the AR coating 3 being made of purely CaF₂. The glass substrate 1 with the resulting coating 3 thereon was then heat treated in furnace at 625° C. for 3 and a half minutes. The optical spectra of this coating 3 on glass substrate 1 is shown as line B in FIG. 3. It can be seen that the transmission through the coated article was not very good, i.e., the coating 3 did not do as good of a job as the MgF₂ AR coating 3 of Example 1. In particular, this CaF₂ coating 3 on substrate 1 of Example 2 was measured to undesirably decrease (not increase) the light transmission through the glass substrate 1 by −9.7%, thereby reducing the power (theoretical energy output) of the photovoltaic device by −12.2% (W/m²). This Example shows that a coating 3 of pure CaF₂ (without silica) is inadequate from an optical perspective.

### EXAMPLE 3

In Example 3, a magnesium fluoride-silica composite AR coating 3 was prepared from the sols of magnesium fluoride sol and silica sol. Magnesium fluoride sol was prepared as described above in Example 1. The silica sol was prepared as follows. A polymeric component of silica was prepared by using 64% wt of n-propanol, 24% wt of Glymo, 7% wt of water and 5% wt of hydrochloric acid. These ingredients were used and mixed for 24 hrs. The coating solution was prepared by using 21% wt of polymeric solution, 7% wt colloidal silica in methyl ethyl ketone supplied by Nissan Chemicals Inc, and 72% wt n-propanol. This was stirred for 2 hrs to give silica sol. The magnesium fluoride sol and silica sol were mixed in 50:50 percent weight ratio for 30 minutes. The coating method onto the glass substrate 1 and subsequent heat treatment were the same as mentioned above in Example 1. The result was a coated article including glass substrate 1 and an AR coating thereon made of a composite of MgF₂ and silica. The optical spectra of this coated article is shown by line A in FIG. 4. Moreover, this MgF₂-silica composite AR coating 3 was measured to increase the light transmission through the glass substrate 1 by 1.0%, thereby increasing the power (theoretical energy output) of the photovoltaic device by 1.1% (W/m²), if used in a solar cell as shown in FIG. 2. Note that in all Examples herein, the power increases for photovoltaic devices assumed a crystalline silicon based photovoltaic solar cell for purposes of reference. This coating 3 was more durable than that of Examples 1-2, and resulted in excellent optical characteristics for the solar cell.

### EXAMPLE 4

In Example 4, a magnesium fluoride-silica composite AR coating 3 was prepared from the sols of magnesium fluoride sol and silica sol. Magnesium fluoride sol was prepared as described above in Example 1. The silica sol was prepared as follows. A polymeric component of silica was prepared by using 64% wt of n-propanol, 24% wt of Glymo, 7% wt of water and 5% wt of hydrochloric acid. These ingredients were used and mixed for 24 hrs. The coating solution was prepared by using 21% wt of polymeric solution, 7% wt colloidal silica in methyl ethyl ketone supplied by Nissan Chemicals Inc, and 72% wt n-propanol. This was stirred for 2 hrs to give silica sol. The magnesium fluoride sol and silica sol were mixed in 20:80 percent weight ratio for 30 minutes. The coating method onto the glass substrate 1 and subsequent heat treatment were the same as mentioned above in Example 1. The result was a coated article including glass substrate 1 and an AR coating thereon made of a composite of MgF₂ and silica. The optical spectra of this coated article is shown by line B in FIG. 4. Moreover, this MgF₂-silica composite AR coating 3 was measured to increase the light transmission through the glass substrate 1 by 1.5%, thereby increasing the power (theoretical energy output) of the photovoltaic device by 1.9% (W/m²), if used in a solar cell as shown in FIG. 2. Note that in all Examples herein, the power increases for photovoltaic devices assumed a crystalline silicon based photovoltaic solar cell for purposes of reference. This coating 3 was more durable than that of Examples 1-2, and resulted in excellent optical characteristics for the solar cell.

### EXAMPLE 5

Example 5 was the same as Examples 3 and 4, except that the magnesium fluoride and silica sols were used in a 10:90 percent weight ratio, respectively. The optical spectra of this coated article is shown by line C in FIG. 4. Moreover, this MgF₂-silica composite AR coating 3 was measured to increase the light transmission through the glass substrate 1 by 2.2%, thereby increasing the power (theoretical energy output) of the photovoltaic device by 2.6% (W/m²), if used in a solar cell as shown in FIG. 2. This coating 3 was more durable than that of Examples 1-2, and resulted in excellent optical characteristics for the solar cell.

### EXAMPLE 6

Example 6 was the same as Examples 3-5, except that the magnesium fluoride and silica sols were used in a 5:95 percent weight ratio, respectively. The optical spectra of this coated article is shown by line D in FIG. 4. Moreover, this MgF₂-silica composite AR coating 3 was measured to increase the light transmission through the glass substrate 1 by 2.4%, thereby increasing the power (theoretical energy output) of the photovoltaic device by 2.9% (W/m²), if used in a solar cell as shown in FIG. 2. This coating 3 was more durable than that of Examples 1-2, and resulted in excellent optical characteristics for the solar cell.

### EXAMPLE 7

In Example 7, a calcium fluoride-silica composite coating was prepared from the sols of calcium fluoride sol and silica sol. Calcium fluoride sol was prepared as described above in Example 2. The silica sol was prepared as described above in Example 3. The calcium fluoride sol and silica sol were mixed in 2:98 percent weight ratio, respectively, for 30 minutes. The coating and heating method were the same as described above in Examples 1-6. The optical spectra of this coated article is shown by line E in FIG. 4. Moreover, this CaF₂-silica composite AR coating 3 was measured to increase the light transmission through the glass substrate 1 by 2.3%, thereby increasing the power (theoretical energy output) of the photovoltaic device by 2.6% (W/m²), if used in a solar cell as shown in FIG. 2. This AR coating 3 was more durable than that of Example 2, and resulted in excellent optical characteristics for the solar cell.

### EXAMPLE 8

In Example 8, the AR coating 3 was a composite of MgF₂, CaF₂, and silica. In other words, the AR coating 3 of this example was a composite of silica and bimetallic fluoride. The magnesium fluoride sol, calcium fluoride sol, and silica sol were prepared as described above in Examples 1-7. Then, the magnesium fluoride sol, the calcium fluoride sol, and the silica sol were mixed in a 1:1:98 percent weight ratio, respectively, and stirred for thirty minutes. The coating technique and subsequent heat treatment were the same as in Examples 1-7. The optical spectra of this coated article is shown by the line in FIG. 5. Moreover, this MgF₂—CaF₂-silica composite AR coating 3 was measured to increase the light transmission through the glass substrate 1 by 2.2%, thereby increasing the power (theoretical energy output) of the photovoltaic device by 2.5% (W/m²), if used in a solar cell as shown in FIG. 2. This AR coating 3 was more durable than that of Examples 1-2, and resulted in excellent optical characteristics for the solar cell.

### EXAMPLE 9

In Example 9, 0.57 grams of magnesium ethoxide was dissolved in 15 ml of propanol-2. Then 4 ml of trifluoro acid (TFA) was added. The solution was stirred for 2 hrs. The experiment was done with Guardian's ExtraClear low iron soda lime silica glass substrate 1. The MgF₂ AR film 3 was deposited on the glass substrate 1 using a spin coating technique with 2650 rpm for 30 secs. The glass 1 with the AR coating 3 thereon was then heat treated in furnace at 625° C. for 3 and half minutes for film curing and/or tempering. This MgF₂ AR coating 3 was measured to increase the light transmission through the glass substrate 1 by 1.6%, thereby increasing the power (theoretical energy output) of the photovoltaic device by 1.7% (W/m²), when used in a solar cell as shown in FIG. 2.

### EXAMPLE 10

In Example 10, the magnesium fluoride sol was prepared as mentioned in Example 9 above. The magnesium fluoride-silica composite coating was prepared from the sols of magnesium fluoride sol and silica sol. The silica sol was prepared by the method described in Example 4. The 10% wt of metal fluoride sol and 90% wt of silica sol were mixed and stirred for 30 minutes. The coating deposition technique onto the glass substrate 1 and the subsequent heat treatment were the same as mentioned above in Example 9. Moreover, this MgF₂-silica composite AR coating 3 of Example 10 was measured to increase the light transmission through the glass substrate 1 by 2.4%, thereby increasing the power (theoretical energy output) of the photovoltaic device by 2.9% (W/m²), if used in a solar cell as shown in FIG. 2. This coating 3 was more durable than that of Example 9, and resulted in excellent optical characteristics for the solar cell.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A photovoltaic device comprising:
a photovoltaic layer and at least a glass substrate on a light incident side of the photovoltaic layer;
an anti-reflection coating provided on the glass substrate, the anti-reflection coating being located on a light-incident side of the glass substrate; and
wherein the anti-reflection coating comprises a layer comprising MgF₂ and silica.

2. The photovoltaic device of claim 1, wherein the anti-reflection coating includes only a single layer comprising MgF₂ and silica, and the anti-reflection coating directly contacts a light incident surface of the glass substrate.

3. The photovoltaic device of claim 1, wherein the anti-reflection coating includes more silica than MgF₂.

4. The photovoltaic device of claim 1, wherein the anti-reflection coating has a refractive index (n) of from about 1.20 to 1.45.

5. The photovoltaic device of claim 1, wherein the anti-reflection coating has a refractive index (n) of from about 1.23 to 1.40.

6. The photovoltaic device of claim 1, wherein the anti-reflection coating has a refractive index (n) of from about 1.25 to 1.35.

7. The photovoltaic device of claim 1, wherein the MgF₂ makes up from about 1 to 45% of the anti-reflection coating.

8. The photovoltaic device of claim 1, wherein the MgF₂ makes up from about 1 to 15% of the anti-reflection coating.

9. The photovoltaic device of claim 1, wherein the anti-reflection coating consists essentially of MgF₂ and silica.

10. The photovoltaic device of claim 1, wherein the glass substrate comprises:

| Ingredient | wt. % |
|---|---|
| SiO₂ | 67–75% |
| Na₂O | 10–20% |
| CaO | 5–15% |
| total iron (expressed as Fe₂O₃) | 0.001 to 0.06% |
| cerium oxide | 0 to 0.30% |

wherein the glass substrate by itself has a visible transmission of at least 90%, a transmissive a* color value of −1.0 to +1.0 and a transmissive b* color value of from 0 to +1.5.

11. A photovoltaic device comprising:
a photovoltaic layer and at least a glass substrate on a light incident side of the photovoltaic layer;
an anti-reflection coating provided on the glass substrate, the anti-reflection coating being located on a light-incident side of the glass substrate; and
wherein the anti-reflection coating comprises a layer comprising (a) magnesium fluoride and/or calcium fluoride, and (b) silica.

12. The photovoltaic device of claim 11, wherein the anti-reflection coating includes only a single layer comprising CaF₂ and silica, and the anti-reflection coating directly contacts a light incident surface of the glass substrate.

13. The photovoltaic device of claim 11, wherein the anti-reflection coating comprises CaF₂, and the anti-reflection coating includes more silica than CaF₂.

14. The photovoltaic device of claim 11, wherein the anti-reflection coating has a refractive index (n) of from about 1.20 to 1.45, more preferably from about 1.23 to 1.40, and even more preferably from about 1.25 to 1.35.

15. The photovoltaic device of claim 11, wherein the anti-reflection coating comprises CaF₂, and wherein the CaF₂ makes up from about 1 to 45% of the anti-reflection coating, more preferably from about 1 to 15% of the anti-reflection coating.

16. The photovoltaic device of claim 11, wherein the anti-reflection coating comprises a layer comprising magnesium fluoride, calcium fluoride, and silica.

17. The photovoltaic device of claim 1, wherein the anti-reflection coating further includes CaF₂.

18. A photovoltaic device comprising:
a photovoltaic layer and at least a glass substrate on a light incident side of the photovoltaic layer;
an anti-reflection coating provided on the glass substrate, the anti-reflection coating being located on a light-incident side of the glass substrate; and
wherein the anti-reflection coating comprises a layer comprising at least one metal fluoride and silica.

19. The photovoltaic device of claim 18, wherein the anti-reflection layer comprises silica and one or both of MgF₂ and CaF₂.

20. A method of making a photovoltaic device, the method comprising:
providing a glass substrate;
mixing a metal fluoride inclusive sol and a silica inclusive sol to form a mixture solution;
depositing the mixture solution including the metal fluoride inclusive sol and the silica inclusive sol onto the glass substrate;
heating the glass substrate with the mixture solution thereon, thereby forming a coated article including an anti-reflective coating on the glass substrate; and
coupling the coated article including the anti-reflective coating and glass substrate to at least a photovoltaic layer in making the photovoltaic device.

21. The method of claim 20, wherein the metal fluoride comprises magnesium fluoride and/or calcium fluoride.
